(19) United States
(12) Patent Application Publication
(10) Pub. No.: US 2019/0363152 A1
(43) Pub. Date: Nov. 28, 2019

(54) DISPLAY DEVICE

(71) Applicant: Sharp Kabushiki Kaisha, Sakai City, Osaka (JP)

(72) Inventors: Yohsuke KANZAKI, Sakai City (JP); Takao SAITOH, Sakai City (JP); Masahiko MIWA, Sakai City (JP); Masaki YAMANAKA, Sakai City (JP); Seiji KANEKO, Sakai City (JP)

(21) Appl. No.: 16/463,455

(22) PCT Filed: Sep. 12, 2017
(86) PCT No.: PCT/JP2017/032880

§ 371 Date: May 23, 2019

(51) Int. Cl. H01L 27/32; H01L 51/00; B32B 7/12; B32B 15/08; B32B 3/26

(52) U.S. Cl. CPC H01L 27/3276; H01L 51/0097; B32B 7/12; B32B 15/08; B32B 3/266; B32B 2307/202; B32B 2255/20; B32B 2255/06; B32B 2457/202; B32B 2307/206; H01L 2251/5338

(57) ABSTRACT

In a part of a frame region defined around a display region, an insulating film having a slit formed on a front surface of the insulating film to extend in a direction intersecting an edge of the display region is provided, and a frame wiring line connected to a light-emitting element of the display region is provided, on the insulating film, to be bent to stride across the slit.

### TECHNICAL FIELD

The disclosure relates to a display device.

### BACKGROUND ART

In recent years, organic EL display devices, which use organic electroluminescence (EL) elements and are of the self-luminous type, have attracted attention as a display device that can replace the liquid crystal display device. As the organic EL display device, a flexible organic EL display device, in which an organic EL element or the like is formed on a flexible resin substrate has been proposed. In the organic EL display device, a display region for displaying images and a frame region formed around the display region, where reduction of the frame region is demanded, are provided. In the flexible organic EL display device, for example, if the frame region is reduced by bending the frame region located on the terminal side, the wiring line arranged in the frame region may be broken.

For example, PTL 1 discloses an active matrix substrate equipped with a signal wiring line being bent in a rectangular wavy form at a display region.

### CITATION LIST

### Patent Literature

PTL 1: WO 2006/022259

### SUMMARY

### Technical Problem

Incidentally, for example, in case when a wiring line being bent in a wavy form is arranged in the frame region on the terminal side, the wiring line may be broken by being twisted, while the wiring line is less liable to be broken by being bent, thus, there is room for improvement.

The disclosure has been made in view of the above, and an object of the disclosure is to prevent a wiring line from being twisted and to thus suppress breakage of the wiring line.

### Solution to Problem

In order to achieve the above-described object, a display device according to the disclosure includes a resin substrate in which a display region for displaying images and a frame region around the display region are defined, a light-emitting element provided in the display region of the resin substrate, and a frame wiring line provided in a part of the frame region along an edge of the display region of the resin substrate, the frame wiring line being connected to the light-emitting element, wherein in a part of the frame region, an insulating film having a slit formed on a front surface of the insulating film is provided to extend in a direction intersecting an edge of the display region, and the frame wiring line is provided, on the insulating film, to be bent to stride across the slit.

### Advantageous Effects of Disclosure

The disclosure, in which the frame wiring line is provided, on the insulating film, to be bent to stride across the slit, makes it possible to prevent a wiring line from being twisted and to thus suppress breakage of the wiring line.

### BRIEF DESCRIPTION OF DRAWINGS

FIG. 1 is a plan view of an organic EL display device according to a first embodiment of the disclosure.

FIG. 2 is a cross-sectional view of the organic EL display device taken along line II-II in FIG. 1.

FIG. 3 is a cross-sectional view illustrating an organic EL layer included in the organic EL display device according to the first embodiment of the disclosure.

FIG. 4 is a plan view illustrating a frame wiring line included in the organic EL display device according to the first embodiment of the disclosure.

FIG. 5 is a perspective view illustrating a frame wiring line included in the organic EL display device according to the first embodiment of the disclosure.

FIG. 6 is a cross-sectional view of a bending section of the organic EL display device taken along the line VI-VI in FIG. 4.

FIG. 7 is a cross-sectional view of a bending section of the organic EL display device taken along the line VII-VII in FIG. 4.

FIG. 8 is a cross-sectional view of a bending section of the organic EL display device taken along the line VIII-VIII in FIG. 4.

FIG. 9 is a cross-sectional view of a bending section in a first modified example of an organic EL display device according to the first embodiment of the disclosure, where FIG. 9 corresponds to FIG. 6.

FIG. 10 is a cross-sectional view of a bending section in a second modified example of an organic EL display device according to the first embodiment of the disclosure, where FIG. 10 corresponds to FIG. 6.

FIG. 11 is a cross-sectional view of a bending section in a third modified example of an organic EL display device according to the first embodiment of the disclosure, where FIG. 11 corresponds to FIG. 6.

FIG. 12 is a cross-sectional view of a bending section in a fourth modified example of an organic EL display device according to the first embodiment of the disclosure, where FIG. 12 corresponds to FIG. 6.

FIG. 13 is a cross-sectional view of a bending section in a fifth modified example of an organic EL display device according to the first embodiment of the disclosure, where FIG. 13 corresponds to FIG. 6.

FIG. 14 is a cross-sectional view of a bending section in a sixth modified example of an organic EL display device according to the first embodiment of the disclosure, where FIG. 14 corresponds to FIG. 6.

FIG. 15 is a cross-sectional view of a bending section of an organic EL display device according to a second embodiment of the disclosure, where FIG. 15 corresponds to FIG. 6.

FIG. 16 is a cross-sectional view of a bending section of an organic EL display device according to the second embodiment of the disclosure, where FIG. 16 corresponds to FIG. 7.

FIG. 17 is a cross-sectional view of a bending section of an organic EL display device according to the second embodiment of the disclosure, where FIG. 17 corresponds to FIG. 8.

FIG. 18 is a cross-sectional view of a bending section of an organic EL display device according to a third embodiment of the disclosure, where FIG. 18 corresponds to FIG. 6.

FIG. 19 is a cross-sectional view of a bending section of an organic EL display device according to the third embodiment of the disclosure, where FIG. 19 corresponds to FIG. 8.

FIG. 20 is a plan view illustrating a frame wiring line included in the organic EL display device according to another embodiment of the disclosure.

### DESCRIPTION OF EMBODIMENTS

Embodiments of the disclosure will be described below in detail with reference to the drawings. The disclosure is not limited to the embodiments described below.

### First Embodiment

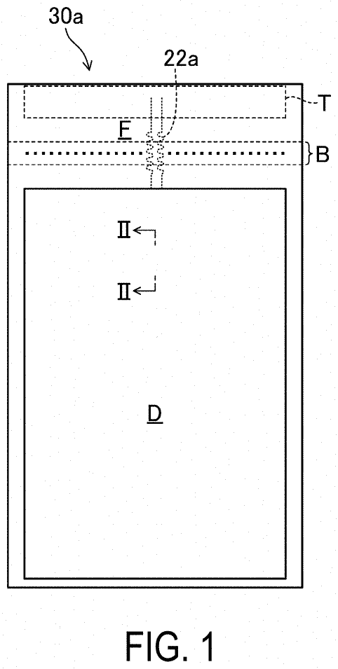

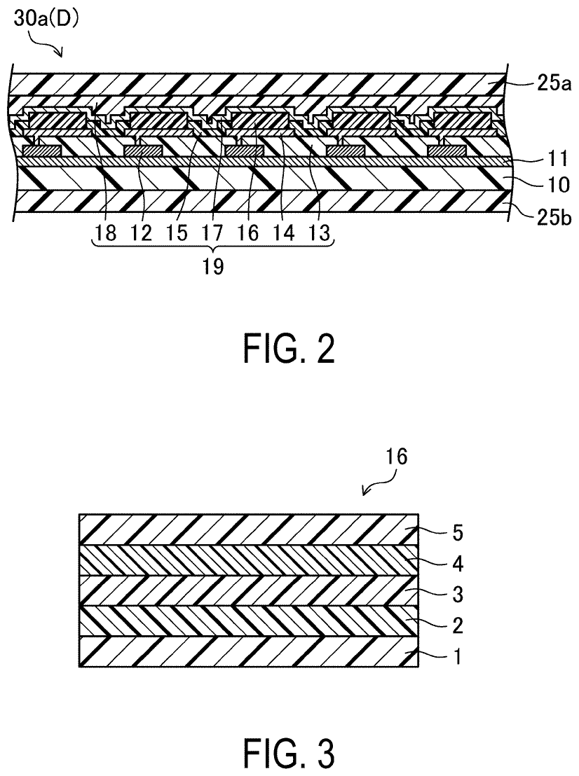

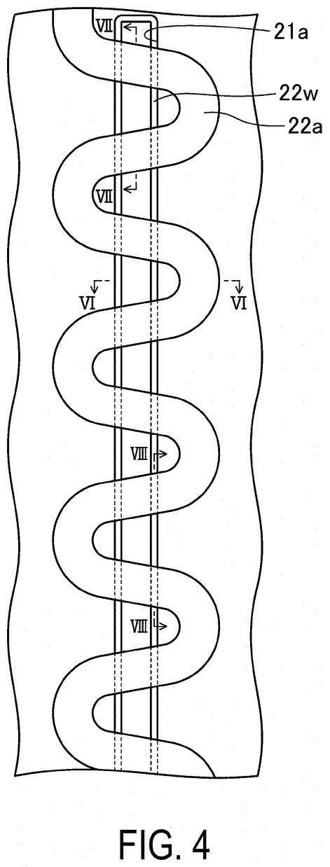

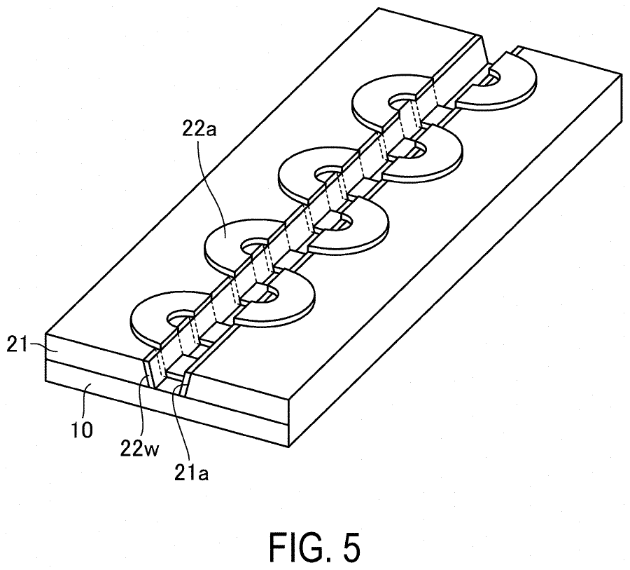

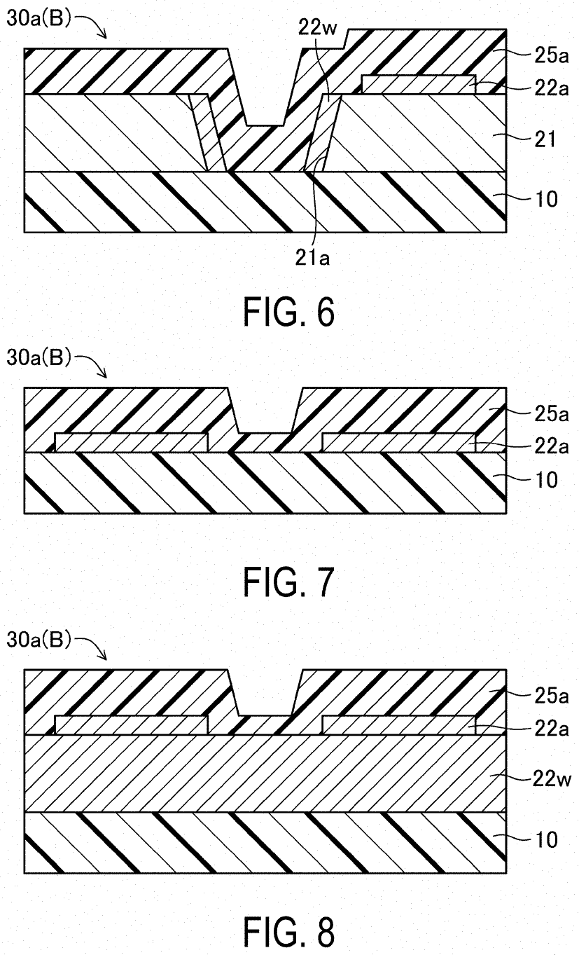

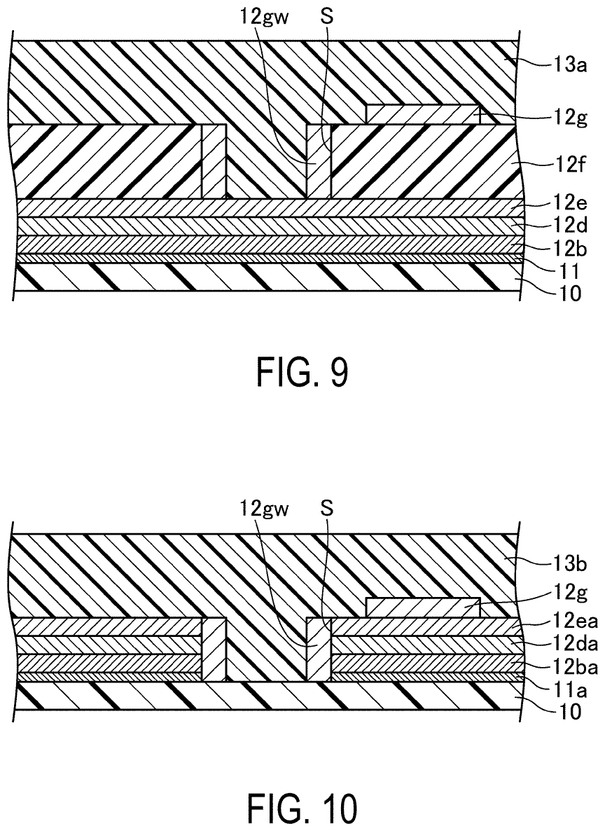

FIG. 1 to FIG. 14 illustrate a first embodiment of a display device according to the disclosure. Note that, in each of the following embodiments, an example of an organic EL display device equipped with organic EL elements is given as a display device equipped with light-emitting elements. FIG. 1 is a plan view of an organic EL display device 30a according to the first embodiment. FIG. 2 is a cross-sectional view of the organic EL display device 30a taken along line II-II in FIG. 1. FIG. 3 is a cross-sectional view illustrating an organic EL layer 16 included in the organic EL display device 30a. FIG. 4 and FIG. 5 are a plan view and a perspective view, respectively, which illustrate a frame wiring line 22a included in the organic EL display device 30a. FIG. 6, FIG. 7, and FIG. 8 are cross-sectional views of a bending section B of the organic EL display device 30a taken along line VI-VI, line VII-VII, and line VIII-VIII in FIG. 4. FIG. 9 to FIG. 14 are cross-sectional views of a bending section B in a first to sixth modified examples in FIG. 1 to FIG. 6 of the organic EL display device 30a, where FIG. 9 to FIG. 14 are views each corresponding to FIG. 6.

As illustrated in FIG. 1, the organic EL display device 30a includes a display region D for displaying images and a frame region F defined around the display region D. As illustrated in FIG. 2, the display region D of the organic EL display device 30a is provided with organic EL elements 19, and in the display region D, a plurality of pixels are arranged in a matrix pattern. Note that each of the pixels in the display region D includes, for example, a subpixel for display of red grayscale, a subpixel for display of green grayscale, and a subpixel for display of blue grayscale. These subpixels are disposed adjacent to one another. As illustrated in FIG. 1, a terminal section T is provided at the upper end portion of the frame region F in the figure. Further, as illustrated in FIG. 1, between the display region D and the terminal section T in the frame region F, a bending section B bendable at 180 degrees (in a U shape) with a bending axis being the horizontal direction in the drawing is provided to be along one side (upper side in the drawing) of an edge of the display region D. Although in the first embodiment, the example of the display region D defined in a rectangle shape is given, the display region D may be defined in another shape such as an elliptical shape or a shape with a cutout.

As illustrated in FIG. 2, the organic EL display device 30a includes, in the display region D, a resin substrate layer 10, a base coat film 11 provided on the front surface of the resin substrate layer 10, an organic EL element 19 provided on the front surface of the base coat film 11, a front surface support base material 25a provided on the front surface of the organic EL element 19, and a back surface support base material 25b provided on the back surface of the resin substrate layer 10.

The resin substrate layer 10, which is formed of, for example, a polyimide resin or the like with a thickness of approximately from 10 μm to 20 μm, is provided as a resin substrate.

The base coat film 11 is formed with, for example, a single layer film or a multilayer film of an inorganic insulating film such as a silicon nitride film, a silicon oxide film, a silicon oxynitride film, or the like.

As illustrated in FIG. 2, the organic EL element 19 includes a plurality of TFTs 12, a flattening film 13, a plurality of first electrodes 14, an edge cover 15, a plurality of organic EL layers 16, a second electrode 17, and a sealing film 18, which are provided in the order stated, over the base coat film 11.

The plurality of TFTs 12 are provided on the base coat film 11 to correspond to the plurality of subpixels. The TFT 12 includes, for example, semiconductor layers provided in an island pattern on the base coat film 11, a gate insulating film provided to cover the semiconductor layers, a gate electrode provided to partially overlap on the gate insulating film with the semiconductor layers, an interlayer insulating film provided to cover the gate electrode, and a source electrode and a drain electrode provided on the interlayer insulating film and arranged in a manner spaced apart from each other. Note that, although in the first embodiment, the top-gate type is described as an example of the TFT 12, the TFT 12 may be of the bottom-gate type.

As illustrated in FIG. 2, the flattening film 13 is provided to cover a portion other than a part of a drain electrode of each TFT 12. The flattening film 13 is formed of, for example, a colorless and transparent organic resin material, such as an acrylic resin.

As illustrated in FIG. 2, the plurality of first electrodes 14 are provided, each corresponding to each subpixel, in a matrix pattern over the flattening film 13. Here, as illustrated in FIG. 2, the first electrode 14 is coupled to the drain electrode of the TFT 12 via a contact hole formed through the flattening film 13. The first electrode 14 functions to inject holes into the organic EL layer 16. It is further preferable that the first electrodes 14 includes a material having a large work function to improve the hole injection efficiency into the organic EL layer 16. Examples of materials that may be included in the first electrode 14 include metal materials, such as silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). Further examples of materials that may be included in the first electrode 14 include alloys, examples of which include magnesium (Mg)-copper (Cu), magnesium (Mg)-silver (Ag), sodium (Na)-potassium (K), astatine (At)-astatine oxide (AtO₂), lithium (Li)-aluminum (Al), lithium (Li)-calcium (Ca)-aluminum (Al), and lithium fluoride (LiF)-calcium (Ca)-aluminum (Al). Further examples of materials that may be included in the first electrode 14 include electrically conductive oxides, examples of which include tin oxide (SnO), zinc oxide (ZnO), indium tin oxide (ITO), and indium zinc oxide (IZO). The first electrode 14 may include a stack of two or more layers of any of the above-mentioned materials. Note that, examples of materials having a large work function include indium tin oxide (ITO) and indium zinc oxide (IZO).

As illustrated in FIG. 2, the edge cover 15 is provided in a lattice pattern and surrounds the outer perimeter portion of each first electrode 14. Examples of materials that may be included in the edge cover 15 include an inorganic film, for example, a silicon oxide (SiO₂) film, a silicon nitride (SiNx (x is a positive number)) film such as a trisilicon tetranitride (Si₃N₄) film, or a silicon oxynitride (SiON) film; and an organic film, for example, a polyimide resin film, an acrylic resin film, a polysiloxane resin film, or a novolak resin film.

As illustrated in FIG. 2, the plurality of organic EL layers 16 are provided in a matrix pattern, each being arranged on each first electrode 14 and each corresponding to each subpixel. As illustrated in FIG. 3, the organic EL layers 16 each include a hole injection layer 1, a hole transport layer 2, a light-emitting layer 3, an electron transport layer 4, and an electron injection layer 5, which are provided in the order stated, over the first electrode 14.

The hole injection layer 1 is also referred to as an anode buffer layer, and functions to reduce the energy level difference between the first electrode 14 and the organic EL layer 16, to improve the hole injection efficiency into the organic EL layer 16 from the first electrode 14. Examples of materials that may be included in the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 functions to improve the efficiency of hole transport from the first electrode 14 to the organic EL layer 16. Examples of materials that may be included in the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where holes and electrons recombine, when a voltage is applied via the first electrode 14 and the second electrode 17, the holes and electrons are injected from the first electrode 14 and the second electrode 17, respectively. The light-emitting layer 3 is formed of a material having high light-emitting efficiency. Examples of materials that may be included in the light-emitting layer 3 include metal oxinoid compounds (8-hydroxyquinoline metal complexes), naphthalene derivatives, anthracene derivatives, diphenyl ethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 functions to facilitate efficient migration of the electrons to the light-emitting layer 3. Examples of materials that may be included in the electron transport layer 4 include organic compounds, example of which include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds.

The electron injection layer 5 functions to reduce the energy level difference between the second electrode 17 and the organic EL layer 16, to improve the efficiency of electron injection into the organic EL layer 16 from the second electrode 17. Because of this function, the driving voltage for the organic EL element 19 can be reduced. Note that the electron injection layer 5 is also referred to as a cathode buffer layer. Examples of materials that may be included in the electron injection layer 5 include inorganic alkaline compound such as lithium fluoride (LiF), magnesium fluoride (MgF₂), calcium fluoride (CaF₂), strontium fluoride (SrF₂), or barium fluoride (BaF₂); aluminum oxide (Al₂O₃); and strontium oxide (SrO).

As illustrated in FIG. 2, the second electrode 17 is disposed to cover the organic EL layers 16 and the edge cover 15. The second electrode 17 functions to inject electrons into the organic EL layer 16. It is further preferable that the second electrode 17 includes a material having a small work function to improve the efficiency of electron injection into the organic EL layer 16. Examples of materials that may be included in the second electrode 17 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). Further examples of materials that may be included in the second electrode 17 include alloys, examples of which include magnesium (Mg)-copper (Cu), magnesium (Mg)-silver (Ag), sodium (Na)-potassium (K), astatine (At)-astatine oxide (AtO₂), lithium (Li)-aluminum (Al), lithium (Li)-calcium (Ca)-aluminum (Al), and lithium fluoride (LiF)-calcium (Ca)-aluminum (Al). Further examples of materials that may be included in the second electrode 17 include electrically conductive oxides, examples of which include tin oxide (SnO), zinc oxide (ZnO), indium tin oxide (ITO), and indium zinc oxide (IZO). The second electrode 17 may include a stack of two or more layers of any of the above-mentioned materials. Note that, examples of materials having a small work function include magnesium (Mg), lithium (Li), lithium fluoride (LiF), magnesium (Mg)-copper (Cu), magnesium (Mg)-silver (Ag), sodium (Na)-potassium (K), lithium (Li)-aluminum (Al), lithium (Li)-calcium (Ca)-aluminum (Al), and lithium fluoride (LiF)-calcium (Ca)-aluminum (Al).

As illustrated in FIG. 2, the sealing film 18 is provided to cover the second electrode 17, and functions to protect the organic EL layer 16 from moisture and oxygen. Examples of materials that may be included in the sealing film 18 include inorganic materials, example of which include silicon oxide (SiO₂), aluminum oxide (Al₂O₃), silicon nitride (SiNx (x is a positive number)) such as trisilicon tetranitride (Si₃N₄), and silicon carbon nitride (SiCN); and organic materials, example of which include acrylate, polyurea, parylene, polyimide, and polyamide.

The front surface support base material 25a and the back surface support base material 25b are each formed with, for example, a polyethylene terephthalate (PET) resin film or the like with a thickness of approximately 100 μm.

As illustrated in FIG. 4 to FIG. 8, the organic EL display device 30a includes, in the frame region F, the resin substrate layer 10, an insulating film 21 provided on the front surface of the resin substrate layer 10, a frame wiring line 22a provided on the front surface of the insulating film 21, and the front surface support base material 25a provided to cover the frame wiring line 22a. The back surface support base material 25b arranged in the display region D is also provided in the most part of the frame region F, but is not provided at the bending section B of the frame region F. Note that, in the plan view and the perspective view of FIG. 4 and FIG. 5, the front surface support base material 25a on the frame wiring line 22a is omitted.

The insulating film 21 is formed with, for example, an organic insulating film such as a polyimide resin film with a thickness of approximately 2 μm. On the front surface of the insulating film 21, a slit 21a is formed to extend in a direction intersecting (for example, orthogonal to) one side (upper side in FIG. 1) of the edge of the display region D. Note that, although in the first embodiment, the example of the insulating film 21 formed with an organic insulating film is given, the insulating film 21 may also be formed with an inorganic insulating film.

The frame wiring line 22a is connected to a signal wiring line (for example, gate line, source line, and power supply line) of the organic EL element 19 in the display region D. The frame wiring line 22a is also formed with, for example, a metal layered film of a titanium film (with a thickness of approximately 100 nm)/an aluminum film (with a thickness of approximately 500 nm)/a titanium film (with a thickness of approximately 50 nm). Note that, although in the first embodiment, the example of the frame wiring line 22a formed with a metal layered film is given, the frame wiring line 22a may also be formed with a metal single layer film. As illustrated in FIG. 4 to FIG. 8, the frame wiring line 22a is also provided, in a wavy form in a plan view on the insulating film 21, to be bent to stride across the slit 21a. As illustrated in FIG. 4 to FIG. 6, and FIG. 8, the frame wiring line 22a includes a sidewall conductive layer 22w provided on the sidewall of the slit 21a of the insulating film 21. The sidewall conductive layer 22w is formed with a metal layered film for forming the frame wiring line 22a.

Note that, although in the first embodiment, the example of the configuration in which the slit 21a is formed in the insulating film 21 provided in the frame region F alone is given, a configuration may be provided in which the slit S is formed in another insulating film as illustrated in FIG. 9 to FIG. 14.

More specifically, in the first modified example of FIG. 9, the TFT layer included in the TFT 12 includes, in the frame region F, a gate insulating film 12b, a first interlayer insulating film 12d, and a second interlayer insulating film 12e that are formed with inorganic insulating film, and a third interlayer insulating film 12f formed with organic insulating film. As illustrated in FIG. 9, a slit S is formed in the third interlayer insulating film 12f to extend in a direction intersecting (for example, orthogonal to) one side (upper side in FIG. 1) of the edge of the display region D. Further, as illustrated in FIG. 9, on the third interlayer insulating film 12f, a frame wiring line 12g formed of the same material in the same layer as the source electrode of the TFT 12 is provided, in a wavy form in a plan view, to be bent to stride across the slit S. As illustrated in FIG. 9, the frame wiring line 12g also includes a sidewall conductive layer 12gw provided on the sidewall of the slit S, and is covered with a flattening film 13a. Further, as illustrated in FIG. 9, the sidewall conductive layer 12gw is in contact with the third interlayer insulating film 12f and the second interlayer insulating film 12e.

In the second modified example of FIG. 10, the TFT layer included in the TFT 12 includes, in the frame region F, a gate insulating film 12ba, a first interlayer insulating film 12da, and a second interlayer insulating film 12ea that are formed with inorganic insulating film. As illustrated in FIG. 10, in a layered film of a base coat film 11a, the gate insulating film 12ba, the first interlayer insulating film 12da, and the second interlayer insulating film 12ea, the slit S is formed to extend in a direction intersecting (for example, orthogonal to) one side (upper side in FIG. 1) of the edge of the display region D. Further, as illustrated in FIG. 10, on the second interlayer insulating film 12ea, the frame wiring line 12g is provided, in a wavy form in a plan view, to be bent to stride across the slit S. As illustrated in FIG. 10, the frame wiring line 12g also includes a sidewall conductive layer 12gw provided on the sidewall of the slit S, and is covered with a flattening film 13b. Further, as illustrated in FIG. 10, the sidewall conductive layer 12gw is in contact with the layered film of the base coat film 11a, the gate insulating film 12ba, the first interlayer insulating film 12da, and the second interlayer insulating film 12ea, and the resin substrate layer 10.

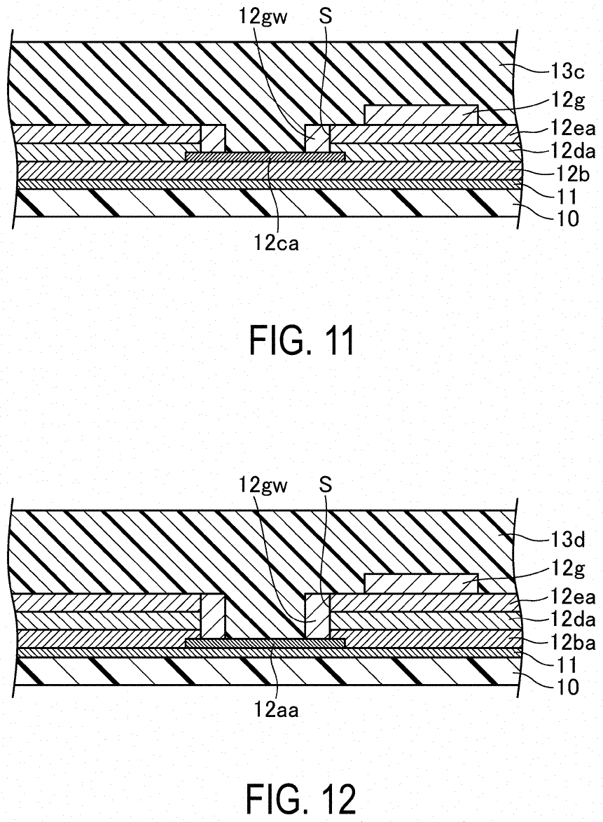

In the third modified example of FIG. 11, the TFT layer included in the TFT 12 includes, in the frame region F, a gate insulating film 12b, a first interlayer insulating film 12da, and a second interlayer insulating film 12ea that are formed with inorganic insulating film. Note that, between the gate insulating film 12b and the first interlayer insulating film 12da, a metal layer 12ca formed of the same material in the same layer as the gate of the TFT 12 and functioning to be an etching stopper when the slit S is formed is provided. As illustrated in FIG. 11, in a layered film of the first interlayer insulating film 12da and the second interlayer insulating film 12ea, the slit S is formed to extend in a direction intersecting (for example, orthogonal to) one side (upper side in FIG. 1) of the edge of the display region D. Further, as illustrated in FIG. 11, on the second interlayer insulating film 12ea, the frame wiring line 12g is provided, in a wavy form in a plan view, to be bent to stride across the slit S. As illustrated in FIG. 11, the frame wiring line 12g also includes a sidewall conductive layer 12gw provided on the sidewall of the slit S, and is covered with a flattening film 13c. Further, as illustrated in FIG. 11, the sidewall conductive layer 12gw is in contact with the layered film of the first interlayer insulating film 12da and the second interlayer insulating film 12ea, and the metal layer 12ca.

In the fourth modified example of FIG. 12, the TFT layer included in the TFT 12 includes, in the frame region F, a gate insulating film 12ba, a first interlayer insulating film 12da, and a second interlayer insulating film 12ea that are formed with inorganic insulating film. Note that, between the base coat film 11 and the gate insulating film 12ba, another semiconductor layer 12aa formed of the same material in the same layer as the semiconductor layer of the TFT 12 and functioning to be an etch stopper when the slit S is formed is provided. As illustrated in FIG. 12, in a layered film of the gate insulating film 12ba, the first interlayer insulating film 12da, and the second interlayer insulating film 12ea, the slit S is formed to extend in a direction intersecting (for example, orthogonal to) one side (upper side in FIG. 1) of the edge of the display region D. Further, as illustrated in FIG. 12, on the second interlayer insulating film 12ea, the frame wiring line 12g is provided, in a wavy form in a plan view, to be bent to stride across the slit S. As illustrated in FIG. 12, the frame wiring line 12g also includes a sidewall conductive layer 12gw provided on the sidewall of the slit S, and is covered with a flattening film 13d. Further, as illustrated in FIG. 12, the sidewall conductive layer 12gw is in contact with the layered film of the gate insulating film 12ba, the first interlayer insulating film 12da, and the second interlayer insulating film 12ea, and the semiconductor layer 12aa.

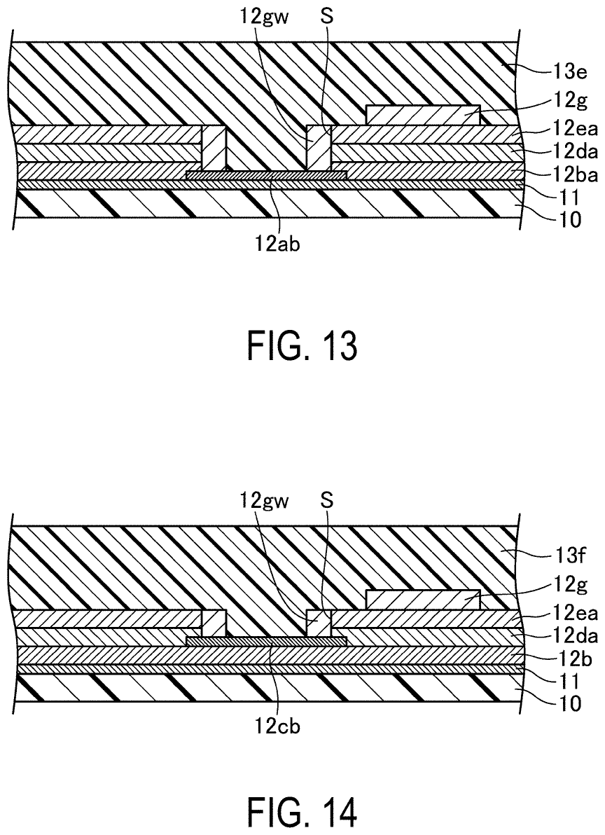

In the fifth modified example of FIG. 13, the TFT layer included in the TFT 12 (of bottom gate type) includes a gate insulating film 12ba, a first interlayer insulating film 12da, and a second interlayer insulating film 12ea that are formed with inorganic insulating film. Note that, between the base coat film 11 and the gate insulating film 12ba, a metal layer 12ab formed of the same material in the same layer as the gate electrode of the TFT 12 and functioning to be an etch stopper when the slit S is formed is provided. As illustrated in FIG. 13, in a layered film of the gate insulating film 12ba, the first interlayer insulating film 12da, and the second interlayer insulating film 12ea, the slit S is formed to extend in a direction intersecting (for example, orthogonal to) one side (upper side in FIG. 1) of the edge of the display region D. Further, as illustrated in FIG. 13, on the second interlayer insulating film 12ea, the frame wiring line 12g is provided, in a wavy form in a plan view, to be bent to stride across the slit S. As illustrated in FIG. 13, the frame wiring line 12g also includes a sidewall conductive layer 12gw provided on the sidewall of the slit S, and is covered with a flattening film 13e. Further, as illustrated in FIG. 13, the sidewall conductive layer 12gw is in contact with the layered film of the gate insulating film 12ba, the first interlayer insulating film 12da, and the second interlayer insulating film 12ea, and the metal layer 12ab.

In the sixth modified example of FIG. 14, the TFT layer included in the TFT 12 (of bottom gate type) includes the gate insulating film 12b, the first interlayer insulating film 12da, and the second interlayer insulating film 12ea that are formed with inorganic insulating film. Note that, between the gate insulating film 12b and the first interlayer insulating film 12da, another semiconductor layer 12cb formed of the same material in the same layer as the semiconductor layer of the TFT 12 and functioning to be an etch stopper when the slit S is formed is provided. As illustrated in FIG. 14, in a layered film of the first interlayer insulating film 12da and the second interlayer insulating film 12ea, the slit S is formed to extend in a direction intersecting (for example, orthogonal to) one side (upper side in FIG. 1) of the edge of the display region D. Further, as illustrated in FIG. 14, on the second interlayer insulating film 12ea, the frame wiring line 12g is provided, in a wavy form in a plan view, to be bent to stride across the slit S. As illustrated in FIG. 14, the frame wiring line 12g also includes a sidewall conductive layer 12gw provided on the sidewall of the slit S, and is covered with a flattening film 13f. Further, as illustrated in FIG. 14, the sidewall conductive layer 12gw is in contact with the layered film of the first interlayer insulating film 12da and the second interlayer insulating film 12ea, and the semiconductor layer 12cb.

The organic EL display device 30a described above has flexibility, and is configured, in each subpixel, such that the light-emitting layer 3 of the organic EL layer 16 is caused to appropriately emit light via the TFT 12 so that images are displayed.

The organic EL display device 30a of the first embodiment can be manufactured as described below.

For example, the organic EL display device 30a can be manufactured such that a base coat film 11 and an organic EL element 19 are formed, using a well-known method, on the front surface of a resin substrate layer 10 formed on a glass substrate, a front surface support base material 25a is applied to the organic EL element 19 via an adhesive layer, and then a back surface support base material 25b is applied to the back surface of the resin substrate layer 10, from which the glass substrate has been peeled off, via an adhesive layer. The frame wiring line 22a of the frame region F is formed when the source electrode and the drain electrode of the TFT 12 that are included in the organic EL element 19 are formed. The insulating film 21 in the frame region F is formed, before the formation of the source electrode and the drain electrode of the TFT 12 that are included in the organic EL element 19, by forming and patterning an organic insulating film such as a polyimide resin film.

As described above, according to the organic EL display device 30a of the first embodiment, the frame wiring line 22a is provided to be bent in a wavy form to stride across the slit S formed in the insulating film 21. Thus, the frame wiring line 22a provided with a portion formed on the front surface of the insulating film 21, a portion formed on the side surface of the slit 21a (the sidewall conductive layer 22w), and a portion formed on the bottom surface of the slit 21a, which forms a three dimensional wiring line pattern, makes it possible to prevent the frame wiring line 22a from being twisted. Accordingly, even if the organic EL display device 30a is caused to be bent at the terminal section T of the frame region F, the frame wiring line 22a, which is prevented from being twisted, makes it possible to prevent a wiring line from being twisted and to thus suppress breakage of the wiring line.

### Second Embodiment

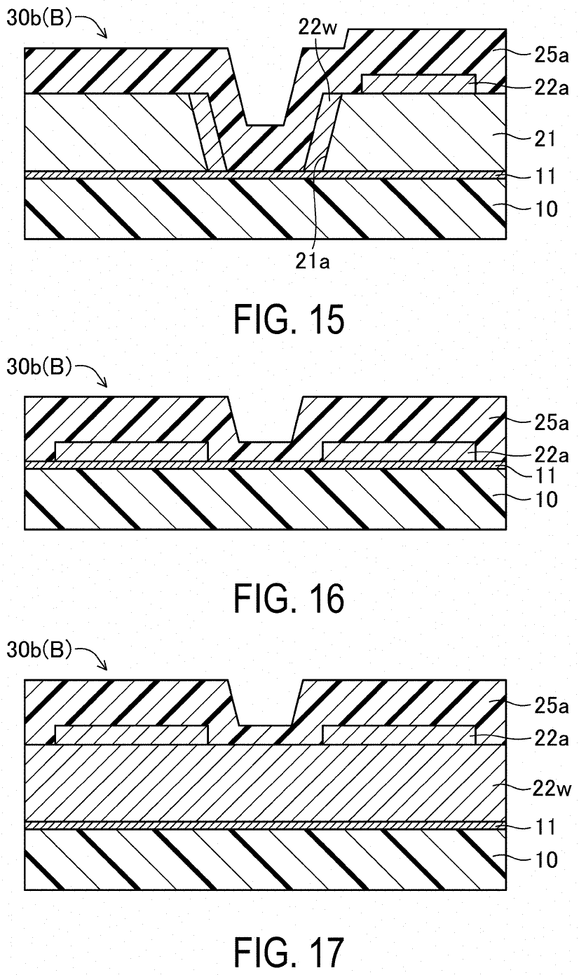

FIG. 15 to FIG. 17 illustrate a second embodiment of the display device according to the disclosure. FIG. 15, FIG. 16, and FIG. 17 are cross-sectional views of a bending section B of an organic EL display device 30b of the second embodiment, where FIG. 15, FIG. 16, and FIG. 17 correspond to FIG. 6, FIG. 7, and FIG. 8. Note that, in the following embodiments, portions identical to those in FIG. 1 to FIG. 14 are denoted by the same reference signs, and their detailed descriptions are omitted.

In the first embodiment, the example of the organic EL display device 30a being devoid of the base coat film 11 is given. However, in the second embodiment, an example of the organic EL display device 30b provided with the base coat film 11 in the frame region F as well is given.

The organic EL display device 30b, like the organic EL display device 30a of the first embodiment, includes the display region D for displaying images and the frame region F defined around the display region D.

The display region D of the organic EL display device 30b has the same configuration as in the organic EL display device 30a of the first embodiment.

As illustrated in FIG. 15 to FIG. 17, the organic EL display device 30b includes, in the frame region F, the resin substrate layer 10, a base coat film 11 provided on the front surface of the resin substrate layer 10, an insulating film 21 provided on the front surface of the base coat film 11, a frame wiring line 22a provided on the front surface of the insulating film 21, and a front surface support base material 25a provided to cover the frame wiring line 22a.

The organic EL display device 30b described above has flexibility as the organic EL display device 30a of the first embodiment, and is configured, in each subpixel, such that the light-emitting layer 3 of the organic EL layer 16 is caused to appropriately emit light via the TFT 12 so that images are displayed.

The organic EL display device 30b of the second embodiment can be manufactured, by modifying the shape of the base coat film 11, in the method for manufacturing the organic EL display device 30a of the first embodiment.

As described above, according to the organic EL display device 30b of the second embodiment, the frame wiring line 22a is provided to be bent in a wavy form to stride across the slit 21a formed in the insulating film 21. Thus, the frame wiring line 22a provided with a portion formed on the front surface of the insulating film 21, a portion formed on the side surface of the slit 21a (the sidewall conductive layer 22w), and a portion formed on the bottom surface of the slit 21a, which forms a three dimensional wiring line pattern, makes it possible to prevent the frame wiring line 22a from being twisted. Accordingly, even if the organic EL display device 30b is caused to be bent at the terminal section T of the frame region F, the frame wiring line 22a, which is prevented from being twisted, makes it possible to prevent a wiring line from being twisted and to thus suppress breakage of the wiring line.

The organic EL display device 30b of the second embodiment, in which the base coat film 11 is provided in the frame region F as well, makes it possible to enhance, in the frame region F, the moisture-proof performance of the resin substrate layer 10.

### Third Embodiment

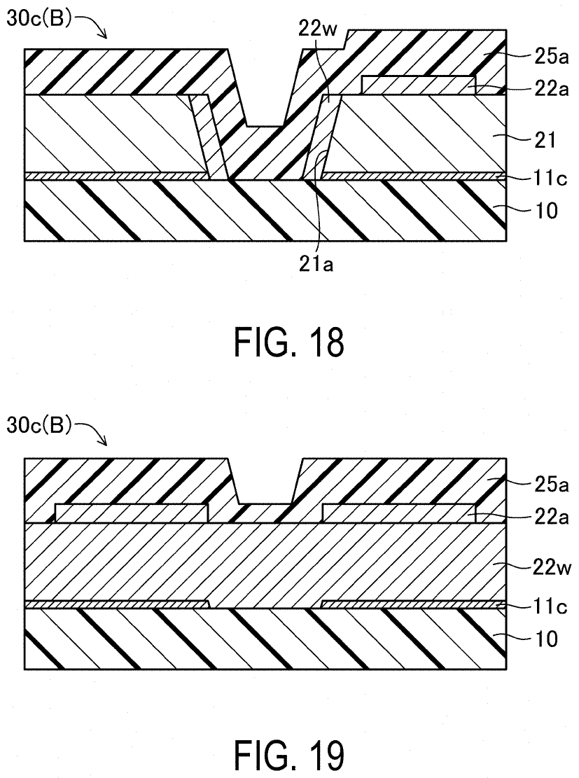

FIG. 18 and FIG. 19 illustrate a third embodiment of the display device according to the disclosure. FIG. 18 and FIG. 19 are cross-sectional views of a bending section B of an organic EL display device 30c of the third embodiment, where FIG. 18 and FIG. 19 correspond to FIG. 6 and FIG. 8. Note that a cross-sectional view corresponding to FIG. 7 of the terminal section T of the organic EL display device 30c of the third embodiment is substantially the same as FIG. 10.

In the second embodiment, the example of the organic EL display device 30b provided with the base coat film 11 in the frame region F as well is given. However, in the third embodiment, an example of the organic EL display device 30c provided with a base coat film 11c patterned in the frame region F is given.

The organic EL display device 30c, like the organic EL display device 30a of the first embodiment, includes the display region D for displaying image and the frame region F defined around the display region D.

The display region D of the organic EL display device 30c has the same configuration as in the organic EL display device 30a of the first embodiment.

As illustrated in FIG. 18 and FIG. 19, the organic EL display device 30c includes, in the frame region F, a resin substrate layer 10, a base coat film 11c provided on the front surface of the resin substrate layer 10, an insulating film 21 provided on the front surface of the base coat film 11c, a frame wiring line 22a provided on the front surface of the insulating film 21, and a front surface support base material 25a provided to cover the frame wiring line 22a.

As illustrated in FIG. 18 and FIG. 19, the portion of the base coat film 11c exposed from the insulating film 21 has been removed. The base coat film 11c is formed of the same material in the same layer as the base coat film 11 provided in the display region D.

The organic EL display device 30c described above has flexibility as the organic EL display device 30a of the first embodiment, and is configured, in each subpixel, such that the light-emitting layer 3 of the organic EL layer 16 is caused to appropriately emit light via the TFT 12 that images are displayed.

The organic EL display device 30c of the third embodiment can be manufactured, by modifying the shape of the base coat film 11, in the method for manufacturing the organic EL display device 30a of the first embodiment.

As described above, according to the organic EL display device 30c of the third embodiment, the frame wiring line 22a is provided to be bent in a wavy form to stride across the slit 21a formed in the insulating film 21. Thus, the frame wiring line 22a is provided with a portion formed on the front surface of the insulating film 21, a portion formed on the side surface of the slit 21a (the sidewall conductive layer 22w), and a portion formed on the bottom surface of the slit 21a, which forms a three dimensional wiring line pattern, makes it possible to prevent the frame wiring line 22a from being twisted. Accordingly, even if the organic EL display device 30c is caused to be bent at the terminal section T of the frame region F, the frame wiring line 22a, which is prevented from being twisted, makes it possible to prevent a wiring line from being twisted and to thus suppress breakage of the wiring line.

The organic EL display device 30c of the third embodiment, in which the base coat film 11c is provided in the frame region F as well and the base coat film 11c has been removed from the portion exposed from the insulating film 21, makes it possible to facilitate bending at the bending section B even if the base coat film 11c is formed of a rigid material.

### Other Embodiments

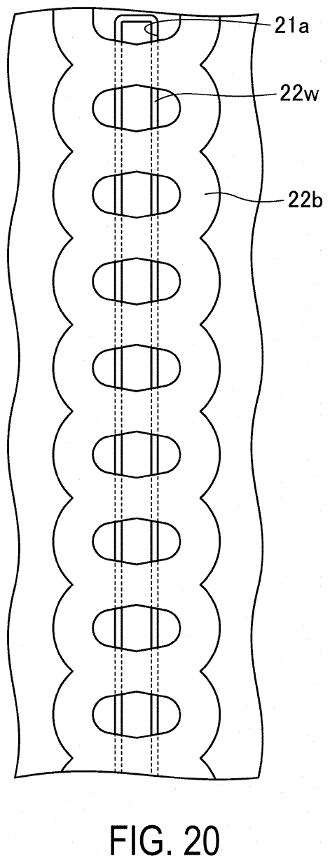

Although in the above-described embodiments, the frame wiring lines 22a is provided in a wavy shape in each of the organic EL display devices 30a to 30c, the frame wiring line may include a frame wiring line 22b as illustrated in FIG. 20. FIG. 20 is a plan view illustrating the frame wiring line 22b included in the organic EL display device of the other embodiment. More specifically, the frame wiring line 22b is connected to a wiring line of the organic EL element 19 in the display region D. The frame wiring line 22b is also formed with, for example, a metal layered film of a titanium film (with a thickness of approximately 100 nm)/an aluminum film (with a thickness of approximately 500 nm)/a titanium film (with a thickness of approximately 50 nm). As illustrated in FIG. 20, the frame wiring line 22b is also provided, in a chain form in a plan view on the insulating film 21, to be bent to stride across the slit 21a. As illustrated in FIG. 20, the frame wiring line 22b also includes a sidewall conductive layer 22w provided on the sidewall of the slit 21a of the insulating film 21. The sidewall conductive layer 22w is formed with a metal layered film for forming the frame wiring line 22b.

Note that, although in the above-described embodiments, the example of the organic EL display device as a display device is given, the disclosure is applicable to a display device equipped with a plurality of light-emitting elements which are driven with power current, for example, a display device equipped with quantum dot light-emitting diodes (QLEDs), which are light-emitting elements using quantum dot-containing layer.

Although in the above-described embodiments, the examples of the frame wiring lines 22a and 22b of single lines are given, the frame wiring lines 22a and 22b may each be redundant by double lines extending in parallel with each other.

In the above-described embodiments, the example of the organic EL layer of the five-layer structure including the hole injection layer, the hole transport layer, the light-emitting layer, the electron transport layer, and the electron injection layer is given. It is also possible that, for example, the organic EL layer may include a three-layer structure including a hole injection-cum-transport layer, a light-emitting layer, and an electron transport-cum-injection layer.

In the above-described embodiments, the example of the organic EL display device including the first electrode as an anode and the second electrode as a cathode is given. However, the disclosure is also applicable to an organic EL display device, in which the layers of the structure of the organic EL layer are in the reverse order, with the first electrode being a cathode and the second electrode being an anode.

In the above-described embodiments, the example of the organic EL display device in which the electrode of the TFT connected to the first electrode serves as the drain electrode is given. However, the disclosure is also applicable to an organic EL display device in which the electrode of the TFT connected to the first electrode is referred to as the source electrode.

### INDUSTRIAL APPLICABILITY

As described above, the disclosure is useful for flexible display devices.

### REFERENCE SIGNS LIST

D Display region
F Frame region
T Terminal section
10 Resin substrate layer (resin substrate)
11, 11c Base coat film
19 Light-emitting element
21a Slit
21 Insulating film
22a, 22b Frame wiring line
22w Sidewall conductive layer
30a to 30c Organic EL display device

1. (canceled)

2. A display device comprising:
a resin substrate in which a display region for displaying images and a frame region around the display region are defined;
a light-emitting element provided in the display region of the resin substrate; and
a frame wiring line provided in a part of the frame region along an edge of the display region of the resin substrate, the frame wiring line being connected to the light-emitting element,
wherein in a part of the frame region, an insulating film having a slit formed on a surface on the insulating film is provided to extend in a direction intersecting the edge of the display region,
the frame wiring line is provided, on the insulating film, to be bent to stride across the slit, and
the frame wiring line includes a sidewall conductive layer provided on a sidewall of the slit.

3. The display device according to claim 1,
wherein the frame wiring line is provided in a wavy form.

4. The display device according to claim 1,
wherein the frame wiring line is provided in a chain form.

5. The display device according to claim 21,
wherein between the resin substrate and the insulating film, a base coat film is provided.

6. The display device according to claim 5,
wherein the slit is formed to pass through the insulating film, and
the base coat film has been removed from a portion exposed from the insulating film.

7. The display device according to claim 21,
wherein at an end portion of the frame region, a terminal section is provided and
the slit is formed between the display region and the terminal section.

8. The display device according to claim 2,
wherein between the resin substrate and the light-emitting element, an inorganic insulating film and an organic insulating film are provided in this order from the resin substrate side,
the slit is formed in the organic insulating film, and
the sidewall conductive layer is in contact with the organic insulating film and the inorganic insulating film.

9. The display device according to claim 2,
wherein between the resin substrate and the light-emitting element, an inorganic insulating film is provided,
the slit is formed in the inorganic insulating film, and
the sidewall conductive layer is in contact with the inorganic insulating film and the resin substrate.

10. The display device according to claim 2,
wherein between the resin substrate and the light-emitting element, a metal layer and an inorganic insulating film are provided in this order from the resin substrate side,
the slit is formed in the inorganic insulating film, and
the sidewall conductive layer is in contact with the inorganic insulating film and the metal layer.

11. The display device according to claim 2,
wherein between the resin substrate and the light-emitting element, a semiconductor layer and an inorganic insulating film are provided in this order from the resin substrate side,
the slit is formed in the inorganic insulating film, and
the sidewall conductive layer is in contact with the inorganic insulating film and the semiconductor layer.

12. The display device according to claim 21,
wherein the light-emitting element includes an organic EL element.
